(19) United States
(12) Patent Application Publication
(10) Pub. No.: US 2023/0290666 A1
(43) Pub. Date: Sep. 14, 2023

(54) SEMICONDUCTOR MANUFACTURING APPARATUS, CARRIER JIG, AND MANUFACTURING METHOD OF SEMICONDUCTOR DEVICE

(71) Applicant: Fasford Technology Co., Ltd., Minami-Alps City (JP)

(72) Inventor: Keita YAMAMOTO, Minami-Alps (JP)

(21) Appl. No.: 18/118,201

(22) Filed: Mar. 7, 2023

(30) Foreign Application Priority Data
Mar. 14, 2022 (JP) 2022-039757

(51) Int. Cl. H01L 21/683; H01L 21/67; H01L 21/687

(52) U.S. Cl. CPC H01L 21/6838; H01L 21/67098; H01L 21/68721

(57) ABSTRACT

A semiconductor manufacturing apparatus includes: a carrier jig including a mounting section having an adsorption hole for adsorbing a substrate to be mounted and a frame section for holding a peripheral edge of the substrate; and a stage including a mounting section having a suction port communicating with the adsorption hole of the carrier jig to adsorb the substrate and a heating device for heating the substrate.

### CLAIM OF PRIORITY

The present application claims priority from Japanese patent application JP2022-39757 filed on Mar. 14, 2022, the content of which is hereby incorporated by reference into this application.

### BACKGROUND

The present disclosure relates to a semiconductor manufacturing apparatus, and is applicable to, for example, a die bonder using a carrier jig.

A semiconductor manufacturing apparatus such as a die bonder is a device that bonds (places and adheres) a semiconductor chip (hereinafter referred to as a die) on a substrate or a die using, for example, a liquid resin or a film-like resin as a bonding material. A substrate is, for example, a wiring substrate, a lead frame formed of a thin metal plate, a glass substrate, or the like. For example, in a die bonder, a substrate is conveyed onto a bond stage including a built-in heating device. Next, a die picked up from a semiconductor wafer (hereinafter simply referred to as a wafer) is conveyed onto the substrate. Furthermore, the die is bonded to the substrate or the like by applying a pressing force to the die and heating a bonding material.

### SUMMARY

When a substrate is conveyed to the stage, the substrate may be deformed to cause conveyance failures, or when the bond stage heats the substrate, the substrate may be deformed.

A problem of the present disclosure is how to provide a technique capable of reducing the deformation of a substrate. Other problems and new features will be explicitly shown by the descriptions of the present specification and the accompanying drawings.

A brief outline of a representative semiconductor manufacturing apparatus shown by the present disclosure is as follows.

To put it concretely, a semiconductor manufacturing apparatus includes: a carrier jig including a mounting section having an adsorption hole for adsorbing a substrate to be mounted and a frame section for holding a peripheral edge of the substrate; and a stage including a mounting section having a suction port communicating with the adsorption hole of the carrier jig to adsorb the substrate and a heating device for heating the substrate.

According to the present disclosure, the deformation of a substrate can be reduced.

### BRIEF DESCRIPTION OF THE DRAWINGS

FIG. 1 is a schematic top view showing a configuration example of a die bonder;

FIG. 2 is a diagram for explaining the schematic configuration of the die bonder when viewed from the direction of an arrow A in FIG. 1;

FIG. 3 is a flow chart showing a manufacturing method of a semiconductor device using the die bonder shown in FIG. 1;

FIG. 4A is a top view showing a state in which a carrier jig is being conveyed to a bond stage of an embodiment;

FIG. 4B is a top view showing a state in which the carrier jig is mounted on the bond stage of the embodiment;

FIG. 4C is a cross-sectional view taken along line A-A shown in FIG. 4B;

FIG. 5A is a top view showing a state in which a substrate is being conveyed to a bond stage of a first comparative example;

FIG. 5B is a top view showing a state in which the substrate is mounted on the bond stage of the first comparative example;

FIG. 5C is a cross-sectional view taken along line A-A shown in FIG. 5B;

FIG. 6A is a top view showing a state in which a carrier jig is being conveyed to a bond stage of a second comparative example;

FIG. 6B is a top view showing a state in which the carrier jig is mounted on the bond stage of the second comparative example;

FIG. 6C is a cross-sectional view taken along line A-A shown in FIG. 6B;

FIG. 6D is a cross-sectional view showing a state in which a substrate held by the carrier jig is heated;

FIG. 7A is a top view showing a carrier jig of a first modification example in a case of one attachment area being large;

FIG. 7B is a top view showing the carrier jig of the first modification example in a case of one attachment area being small;

FIG. 8 is a top view showing a state in which a carrier jig is being conveyed to a bond stage of a second modification example;

FIG. 9A is a top view showing a state in which a carrier jig is being conveyed to a bond stage of a third modification example;

FIG. 9B is a top view showing a state in which the carrier jig is mounted on the bond stage of the third modification example;

FIG. 9C is a cross-sectional view taken along line A-A shown in FIG. 9B;

FIG. 10A is a top view showing a state in which a carrier jig is being conveyed to a bond stage of a fourth modification example;

FIG. 10B is a top view showing a state in which the carrier jig is mounted on the bond stage of the fourth modification example;

FIG. 10C is a front view of the bond stage shown in FIG. 10A; and

FIG. 10D is a cross-sectional view taken along line A-A shown in FIG. 10B.

### DESCRIPTION OF THE PREFERRED EMBODIMENTS

An embodiment, a plurality of comparative examples, and a plurality of modification examples will be described below with reference to the accompanying drawings. Here, in the following descriptions, the same components are given the same reference signs, and repeated descriptions may be omitted in some cases. In addition, there are some cases where, in order to make the descriptions clearer in the accompanying drawings, the widths, thicknesses, shapes, and the like of respective portions of the embodiment, the comparative examples, and the modification examples are schematically depicted differently from what they really are. Furthermore, the dimensions, ratios, and the like of individual components do not always coincide with one another between the plural accompanying drawings.

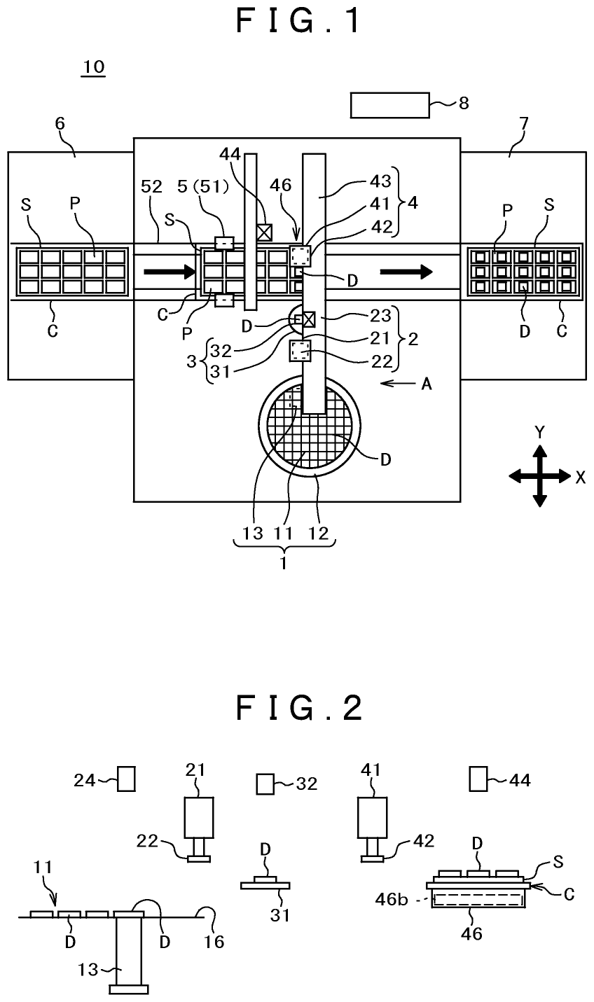

The configuration of a die bonder, which is an embodiment of a semiconductor manufacturing apparatus, will be explained with reference to FIG. 1 and FIG. 2.

Roughly speaking, a die bonder 10 includes: a die supply unit 1 that supplies a die D to be mounted on a substrate S; a pickup s unit 2; an intermediate stage unit 3; a bonding unit 4; a conveyance unit 5; a substrate supply unit 6; a substrate carrying-out unit 7; and a control unit (control device) 8 that monitors and controls the operations of the above individual units. The Y-axis direction is the front-back direction of the die bonder 10, and the X-axis direction is the left-right direction. The die supply unit 1 is disposed on the front side of the die bonder 10, and the bonding unit 4 is disposed on the rear side. Here, a plurality of product areas (hereinafter referred to as package areas P) each of which eventually forms one package are formed on the substrate S.

The die supply unit 1 includes: a wafer hold board 12 for holding a wafer 11; and a peeling unit 13 shown by a dotted line for peeling a die D from the wafer 11. The wafer hold board 12 is moved in the X-axis direction or Y-axis direction by unshown driving means, and moves a die D to be picked up to the position of the peeling unit 13. The peeling unit 13 is moved in the vertical direction by unshown driving means. The wafer 11 is sticked on a dicing tape 16 and divided into a plurality of dies D. The dicing tape 16 to which the wafer 11 is attached is held by an unshown wafer ring. A film-like adhesive material called a die attach film (DAF) 18 is attached between the wafer 11 and the dicing tape 16. In a case where of the wafer 11 to which the die attach film 18 is attached, dicing is performed on both wafer 11 and die attach film 18.

Therefore, in the peeling process, a piece of the wafer 11 and a piece of the die attach film 18 corresponding to a die to be picked up are peeled from the dicing tape 16. The die attach film 18 is hardened by heating.

The pickup unit 2 includes: a pickup head 21; a Y driving unit 23; unshown driving units for lifting or lowering, rotating, and moving a collet 22 in the X-axis direction respectively; and a wafer recognition camera 24. The pickup head 21 includes the collet 22 that adsorbs and holds a peeled die D at its tip, picks up the die D from the die supply unit 1, and mounts the die D on an intermediate stage 31. The Y driving unit 23 moves the pickup head 21 in the Y-axis direction. The wafer recognition camera 24 grasps the pickup position of a die D to be picked up from the wafer 11.

The intermediate stage unit 3 includes the intermediate stage 31 on which a die D is temporarily mounted and a stage recognition camera 32 for recognizing the die D on the intermediate stage 31.

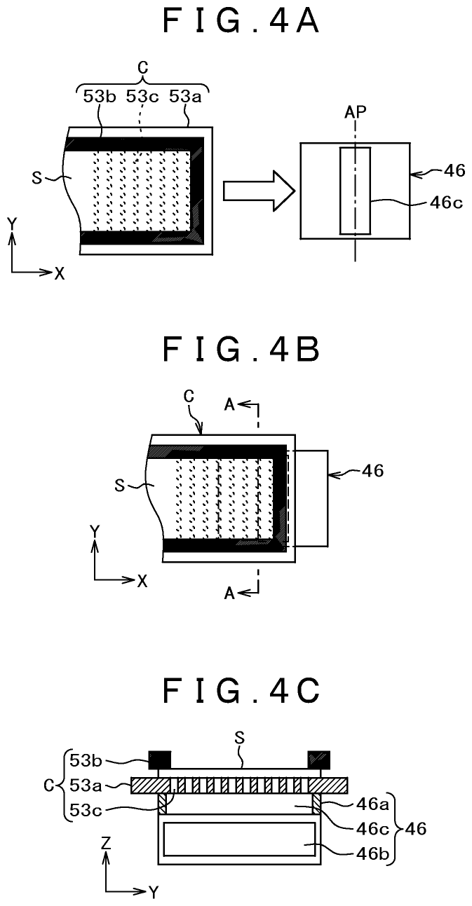

The bonding unit 4 includes: a bond head 41; a Y-axis driving unit 43; a substrate recognition camera 44; and a bond stage 46. The bond head 41 includes a collet 42 that adsorbs and holds a die D at its tip as is the case with the pickup head 21. The Y driving unit 43 moves the bond head 41 in the Y-axis direction. The substrate recognition camera 44 photographs the position recognition mark (not shown) of a package area P of the substrate S, and recognizes a bond position for a die D to be bonded. The bond stage 46 is raised when a die D is mounted on the substrate S, and supports a carrier jig C on which the substrate S is mounted from below. The bond stage 46 includes a suction port 46c (Refer to FIG. 4) for vacuum adsorbing the substrate S, so that the carrier jig C and the substrate S can be fixed. The bond stage 46 includes a heating unit 46b for heating the substrate S. With the use of such a configuration, the bond head 41 corrects the pickup position/posture of a die D on the basis of photographed data taken by the stage recognition camera 32, and picks up the die D from the intermediate stage 31. And then, the bond head 41 bonds the die D on the package area P of the substrate S or bonds the die D on a die D already-bonded on the package area P of the substrate S in a laminated manner on the basis of photographed data taken by the substrate recognition camera 44.

The conveyance unit 5 includes: conveyance claws 51 for grasping and conveying a carrier jig C on which the substrate S is mounted; and a pair of conveyance lanes 52 along which the carrier jig C moves. The carrier jig C is moved in the X-axis direction by driving unshown nuts of the conveyance claws 51 provided for the pair of conveyance lanes 52 using unshown ball screws provided along the pair of conveyance lanes 52. With the use of such a configuration, the carrier jig C is moved from the substrate supply unit 6 to the bond position along the pair of conveyance lanes 52, and after the die D is bonded, the carrier jig C is moved to the substrate carrying-out unit 7 and handed over to the substrate carrying-out unit 7.

The control unit 8 includes a memory that stores a program (software) for monitoring and controlling the operation of each unit of the die bonder 10; and a central processing unit (CPU) that executes the program stored in the memory.

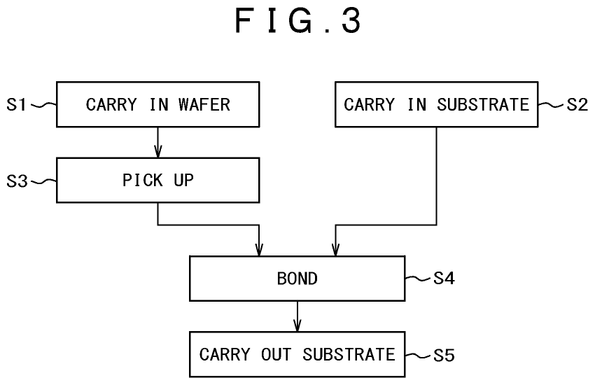

The bonding process that is one process of the manufacturing processes of a semiconductor device (one process of the manufacturing method of a semiconductor device) using the die bonder 10 will be explained with reference to FIG. 3. In the following explanations, it will be assumed that the operations of the individual unit s that compose the die bonder 10 are controlled by the control unit 8.

(Wafer Carrying-In Process (Process S1))

A wafer ring (not shown) is carried in the die bonder 10. The carried-in wafer ring is supplied to the die supply unit 1. Here, a dicing tape 16 to which dies D divided from the wafer 11 are attached is held by the wafer ring.

(Substrate Carrying-In Process (Process S2))

The carrier jig C on which a substrate S is mounted is stored in the substrate supply unit 6 and carried in the die bonder 10. In the substrate supply unit 6, the carrier jig C is fixed by the conveyance claws 51.

(Pickup Process (Process 3))

After the process S1, the wafer hold board 12 is moved so that a desired die D can be picked up from the dicing tape 16. The die D is photographed by the wafer recognition camera 24, and positioning and surface inspection of the die D are performed on the basis of image data obtained by the photographing.

The die D on which the positioning is performed is peeled off from the dicing tape 16 by the peeling unit 13 and the pickup head 21. The die D peeled off from the dicing tape 16 is adsorbed and held by the collet 22 installed in the pickup head 21, conveyed to the intermediate stage 31, and mounted thereon.

The die D on the intermediate stage 31 is photographed by the stage recognition camera 32, and positioning and surface inspection of the die D are performed on the basis of image data obtained by the photographing. By performing image processing on the image data, the deviation amounts (in the X-axis, Y-axis, and θ directions) of the die D on the intermediate stage 31 from the die position reference point of the die bonder are calculated, and the positioning of the die D is performed. Here, a predetermined position of the intermediate stage 31 is held in advance as the die position reference point in the initial setting of the present apparatus. By performing image processing on the image data, the surface inspection of the die D is performed.

After conveying the die D to the intermediate stage 31, the pickup head 21 is returned to the die supply unit 1. The next die D is peeled off from the dicing tape 16 according to the procedure described above, and thereafter dies D are peeled off one by one from the dicing tape 16 according to the same procedure.

(Bonding Process (Process S4))

The carrier jig C is conveyed to the bond stage 46 by the conveyance unit 5. The substrate S mounted on the bond stage 46 via the carrier jig C is photographed by the substrate recognition camera 44, and image data is obtained by the photographing. By performing image processing on the image data, the deviation amounts (in the X-axis, Y axis, and θ directions) of the substrate S from the substrate position reference point of the die bonder 10 are calculated. Here, a predetermined position of the bonding unit 4 is held in advance as the substrate position reference point in the initial setting of the present apparatus.

After the adsorption position of the bond head 41 is corrected with reference to the deviation amounts of the die D on the intermediate stage 31 calculated at the process S3, the die D is adsorbed by the collet 42. The die D is bonded to a predetermined portion of the substrate S supported by the bond stage 46 by the bond head 41 that has adsorbed the die D from the intermediate stage 31. The die D bonded to the substrate S is photographed by the substrate recognition camera 44, and an inspection whether the die D is bonded to the predetermined portion and the like are performed on the basis of image data obtained by the photographing.

After bonding the die D to the substrate S, the bond head 41 is returned to the intermediate stage 31. The next die D is picked up from the intermediate stage 31 according to the procedure described above, and bonded to the substrate S. Thereafter this is repeated, and dies D are attached one by one to all the package areas P of the substrate S.

(Substrate Carrying-Out Process (Process S5))

The carrier jig C on which the substrate S with the die D bonded thereon is conveyed to the substrate carrying-out unit 7. At the substrate carrying-out unit 7, the carrier jig C is taken out from the conveyance claws 51. The carrier jig C on which the substrate S is mounted is carried out from the die bonder 10.

As described above, the die D is bonded to the substrate S and carried out from the die bonder 10. The carrier jig C on which the substrate S with the die D is mounted thereon is conveyed to the wire bonding process, and the electrodes of the die D are electrically connected to electrodes of the substrate S via Au wires and the like. In a case of lamination bonding, next, for example, a carrier jig C on which a substrate S with a die D is mounted thereon is carried in the die bonder, and a die D is laminated on the die D mounted on the substrate S, and the carrier jig C is carried out from the die bonder. After that, the electrodes of the newly laminated die D are electrically connected to electrodes of the substrate S via Au wires in the wire bonding process. A die D to be laminated on a die D on the second stage or a higher stage is peeled off from the dicing tape 16 by the method described above, and then conveyed to the bonding unit, and laminated on the die D on the second stage or a higher stage. After the above process is repeated predetermined times, the substrate S is conveyed to the mold process, and a laminated package is completed by sealing the plurality of dies D and Au wires with a mold resin (not shown).

The carrier jig and the bond stage of the embodiment will be explained with reference to FIG. 4A, FIG. 4B, and FIG. 4C.

The carrier jig C includes a mountling section 53a and a frame section 53b. The mounting section 53a includes a plurality of adsorption holes 53c penetrating the mounting section 53a in the vertical direction (Z-axis direction). In the mounting section 53a, the plurality of adsorption holes 53c are formed in the shape of a grid. In other words, assuming that a certain number of adsorption holes 53c disposed in the column direction (Y-axis direction) form one column, the plurality of adsorption holes 53c form a plurality of columns disposed in the row direction (X-axis direction). A substrate S is mounted on the mounting section 53a. The peripheral edge of the substrate S mounted on the mounting section 53a is pressed from above by the frame section 53b, so that the substrate S is sandwiched and fixed to the mounting section 53a. For example, it is conceivable that the frame section 53b is made of stainless steel that is a magnetic material, and magnets are installed inside of the peripheral edge of the mounting section 53a. The carrier jig C is conveyed to the bond stage 46 along the X-axis direction. Package areas P are disposed in the shape of a grid on the substrate S. At least one adsorption hole 53c is positioned under one package area P.

The bond stage 46 includes a mounting section 46a and a heating unit (heating device) 46b. The mounting section 46a includes the suction port 46c penetrating the mounting section 46a in the vertical direction. The suction port 46c is large enough to accommodate all of a plurality of suction holes 53c of at least one column. The suction port 46c is connected to an unshown decompression device. For example, the central position of the width (the length in the X-axis direction) of the suction port 46c is referred to as an attachment point AP. The attach point AP is a point within the bond stage 46 where dies D are bonded to the substrate S. The bond stage 46 can be moved in the vertical direction. When the carrier jig C is moved, the bond stage 46 is in a lowered state. The carrier jig C is mounted on the mounting section 46a.

When a column of package areas P at the top in the moving direction of the substrate S mounted on the carrier jig C is conveyed above the attach point AP of the bond stage 46, the bond stage 46 is raised to a height where the bond stage 46 contacts the bottom surface of the mounting section 53a of the carrier jig C. The carrier jig C is adsorbed by the suction port 46c and fixed to the bond stage 46. At this time, the plurality of adsorption holes 53c and the suction port 46c communicate with one another, and the substrate S is adsorbed via the carrier jig C and fixed to the bond stage 46. The substrate S is heated by the heating unit 46b via the mounting section 46a and the carrier jig C, so that a plurality of dies D are bonded to the column of package areas P of the substrate S.

After the dies D are bonded to all package areas P of the column of package areas P, the carrier jig C is moved in the X-axis direction so that the next column of package areas P is positioned at the attachment point AP of the bond stage 46. The carrier jig C is moved at the same conveyance pitch as the disposition pitch of the package areas P in the X-axis direction. At this time, the plurality of adsorption holes 53c are disposed and the size of the suction port 46c is set so that at least one column of adsorption holes 53c of the carrier jig C is positioned within the suction port 46c without fail.

Depending on a product to be produced, the disposition pitch (substrate layout) of a package area P in the X-axis direction or Y-axis direction may differ. Even when handling products with different substrate layouts, the adsorption holes 53c are disposed and the size of the suction port 46c is set sufficiently large as well so that at least one column of absorption holes 53c of the carrier jig C is positioned within the suction port 46c without fail. In addition, a setting is made so that at least one adsorption hole 53c is positioned under one package area P. Here, it may be necessary to change the size of the suction port 46c depending on a product to be produced. In this case, by changing the size of the suction port 46c, the carrier jig can be applied to more products and can be used in common among more products.

Since the carrier jig C and the bond stage 46 are rigid bodies, a gap may occur between them. For this reason, it is preferable to use a heat-resistant material such as silicon rubber or fluorocarbon rubber as packing in order to compensate for the gap between the carrier jig C and the bond stage 46.

In order to make the present embodiment more clearly understood, some comparative examples will be described.

### First Comparative Example

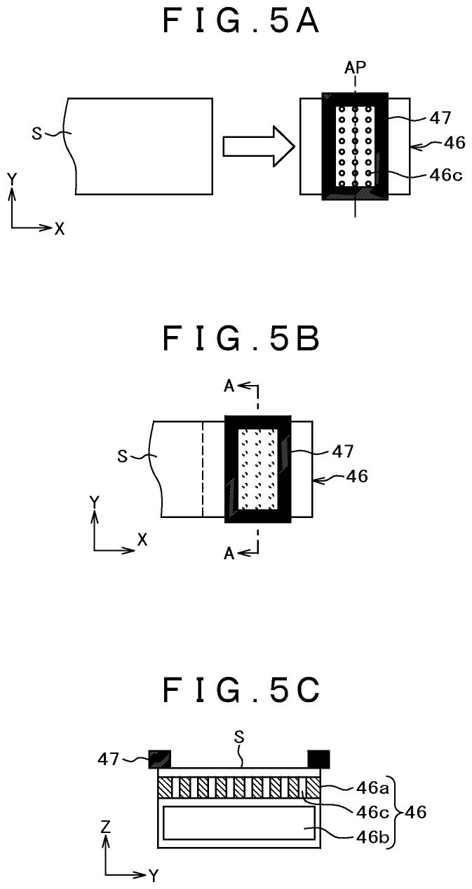

A bond stage of a first comparative example will be explained with reference to FIG. 5A, FIG. 5B, and FIG. 5C.

A bond stage 46 of the first comparative example includes a mounting section 46a and a heating unit 46b. The mounting section 46a includes suction ports 46c as a plurality of adsorption holes each penetrating the mounting section 46a in the vertical direction. It will be assumed that a column of suction ports includes, for example, eight suction ports 46c in the column direction (Y-axis direction), and, for example, three columns of suction ports 46c are formed in the row direction (X-axis direction) in the mounting section 46a. The suction ports 46c are connected to an unshown decompression device. The bond stage 46 can be moved in the vertical direction. When a substrate S is moved, the bond stage 46 is in a lowered state. The substrate S is mounted on the mounting section 46a. Furthermore, the bonding unit 4 includes a frame section 47 that is vertically movable. When the substrate S moves, the frame section 47 is in a raised state.

When the substrate S is conveyed above the attach point AP of the bond stage 46, the bond stage 46 is raised to a height where the bond stage 46 contacts the bottom surface of the substrate S. The frame section 47 descends, and the peripheral edge of the substrate S is pressed from above, so that the substrate S is sandwiched and fixed to the mounting section 53a. The substrate S is adsorbed by the suction ports 46c and fixed to the bond stage 46. The substrate S is heated by the heating unit 46b.

In semiconductor devices, the thicknesses of substrates are being reduced in order to increase the integration densities and capacities of semiconductor devices. For example, dies are laminated to increase the capacity of a semiconductor device, so that a substrate is repeatedly conveyed to laminate the dies. In the first comparative example, there is a possibility that a substrate S is deformed due to repeated conveyance of the substrate S and the lamination of dies D, so that the conveyance failures of the substrate S may occur before the substrate S is conveyed to the bond stage 46.

### Second Comparative Example

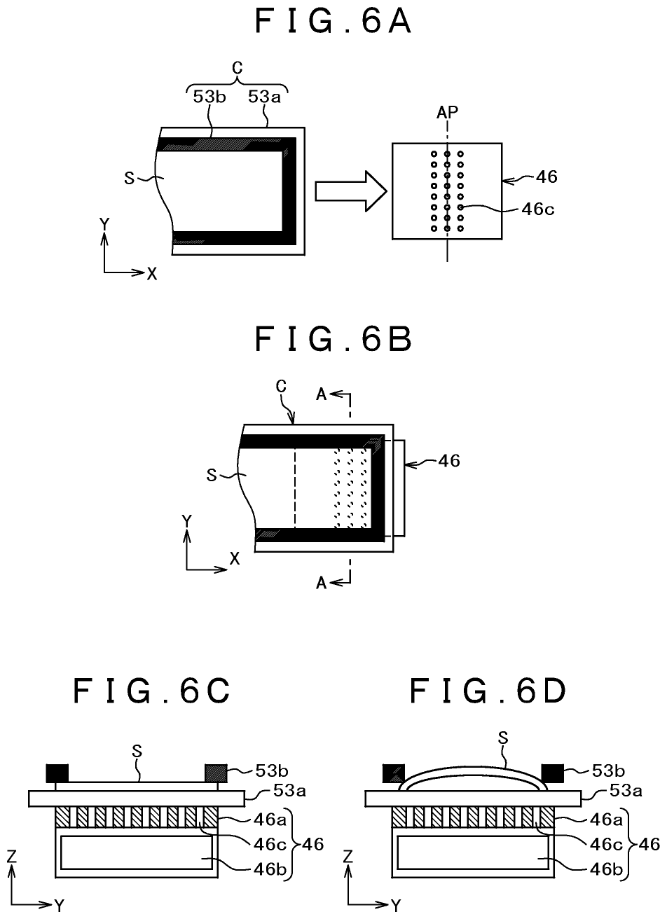

In a second comparative example, a substrate S is held using a carrier jig in order to suppress the deformation of the substrate S. The second comparative example will be explained with reference to FIG. 6A, FIG. 6B, FIG. 6C, and FIG. 6D.

In the second comparative example, a carrier jig C that can move along a pair of conveyance lanes is installed in the configuration of the bond stage of the first comparative example. The carrier jig C includes a mounting section 53a and a frame section 53b. The peripheral edge of a substrate S mounted on the mounting section 53a is pressed from above by the frame section 53b, so that the substrate S is sandwiched and fixed to the mounting section 53a. As a result, as is the case with the embodiment, the substrate can be conveyed while the deformation of the substrate S is being suppressed.

When the carrier jig C is conveyed above the attach point AP of the bond stage 46, the bond stage 46 is raised to a height where the bond stage 46 contacts the bottom surface of the mounting section 53a of the carrier jig C. At this time, the carrier jig C is adsorbed by the suction ports 46c and fixed to the bond stage 46. The substrate S is heated via the carrier jig C by the heating unit 46b.

Unlike the embodiment, the substrate S is not adsorbed. Therefore, when the substrate S is heated by the heating unit 46b built in the bond stage 46, portions other than portions held by the frame section 53b are affected by the heat, and the substrate S is deformed. Due to the deformation of the substrate S, the substrate S may not be recognized by the photographing of the substrate recognition camera 44, and a recognition error may occur.

According to the embodiment, one or more of the following effects can be obtained.

(a) Since the substrate is held by the carrier jig, it is possible to suppress the deformation of the substrate and reduce conveyance failures.

(b) Since the carrier jig is provided with the adsorption holes, these adsorption holes communicate with the suction port of the bond stage to adsorb the substrate. With this, the deformation of the substrate due to heating by the bond stage can be reduced.

(c) Since the deformation of the substrate due to the heating can be reduced, substrate recognition can be performed.

(d) By enlarging the suction port of the bond stage, it becomes possible to determine the area of the carrier jig to be suctioned. In addition, since the carrier jig includes a plurality of small-diameter adsorption holes, the area of the substrate to be held can be adsorbed. As a result, if the sizes of a plurality of substrates are the same, the carrier jig can be shared even if the layouts of the substrates are different from one another, so that the number of types of carrier jigs can be reduced.

### Modification Examples

Several representative modification examples will be illustrated below. In the descriptions of modification examples below, the same reference signs as in the above-described embodiment may be used for components having the same configurations and functions as those described in the above-described embodiment. Furthermore, for the descriptions of these components, the above-described descriptions used in the embodiment can also be used as long as the descriptions are not technically inconsistent. In addition, a part of the above-described embodiment, parts of the above-described comparative examples, and all or some of a plurality of modification examples may be applied appropriately or in combination within a technically consistent range.

### First Modification Example

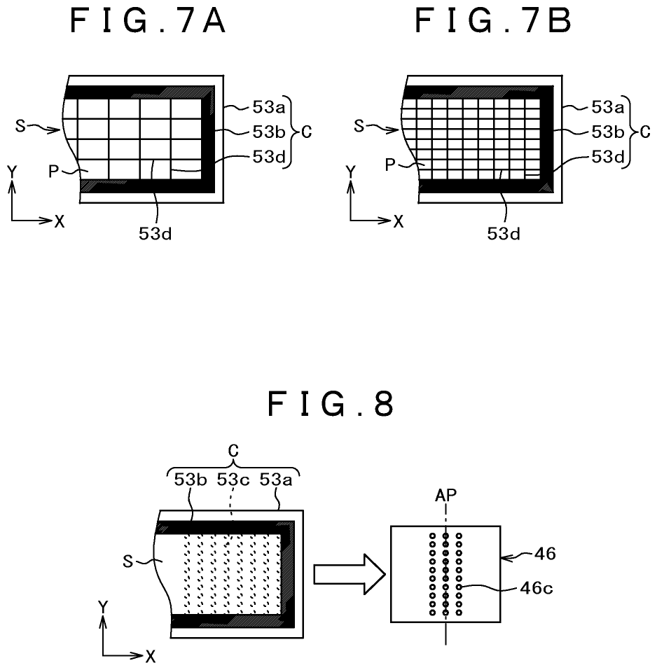

In a first modification example, in order to suppress the deformation of a substrate S during heating by a bond stage, another frame section is added to the carrier jig of the second comparative example for holding the substrate S. The carrier jig of the first modification example will be explained with reference to FIG. 7A and FIG. 7B.

A bond stage 46 of the first modification example has the same configuration as that of the bond stage 46 of the second comparative example. The carrier jig of the first modification example is equivalent to the carrier jig C of the second comparative example to which another frame section 53d is added. Not only the frame section 53b is disposed on the peripheral edge of the substrate S but also a frame section 53d is disposed on the boundaries of package areas P disposed on the substrate S in the shape of a grid, so that floating of the substrate S can be further suppressed.

In the first modification example, different carrier jigs C are required for substrate layouts having the sizes of their package areas P different from one another, so that universality is lacking. Therefore, the first modified example is useful when substrate layouts are the same.

### Second Modification Example

In a second modification example, in order to suppress the deformation of a substrate S due to heating by a bond stage, a carrier jig C that has the same configuration as the configuration of the carrier jig C of the embodiment is installed in the configuration of the bond stage of the first comparative example. The second modification example will be explained with reference to FIG. 8.

The configuration of the carrier jig C of the second modification example is the same as that of the carrier jig C of the embodiment. The configuration of the bond stage 46 of the second modification example is the same as that of the bond stage 46 of the first comparative example.

Considering variations in conveyance of the carrier jig C, the diameter of a suction port 46c and the diameter of an adsorption hole 53c are made different from each other. The diameter of the suction port 46c is set larger or smaller than the diameter of the adsorption hole 53c by the variation of the diameter of the suction port 46c. Here, a distance (pitch) between centers of any two adjacent adsorption holes among a plurality of adsorption holes 53c disposed in the Y-axis direction and a pitch of any two adjacent suction ports among a plurality of suction ports 46c disposed in the Y-axis direction are set equal to each other. Furthermore, a pitch of any two adjacent adsorption holes among a plurality of adsorption holes 53c disposed in the X-axis direction and a pitch of any two adjacent suction ports among a plurality of suction ports 46c disposed in the X-axis direction are set equal to each other.

In the configuration of the second modification example, carrier jigs C having different conveyance pitches are required for package areas P of different sizes. Since the disposition pitch of the adsorption holes 53c is constant, if the conveyance pitch of the carrier jig C is different from the disposition pitch of the adsorption holes 53c, the position of the adsorption holes 53c and the position of the suction ports 46c may not match. The adsorption holes 53c of the carrier jig C do not communicate with the suction ports 46c of the bond stage 46, so that the substrate S may not be adsorbed. Therefore, the second modification example is useful when substrate layouts are the same.

### Third Modification Example

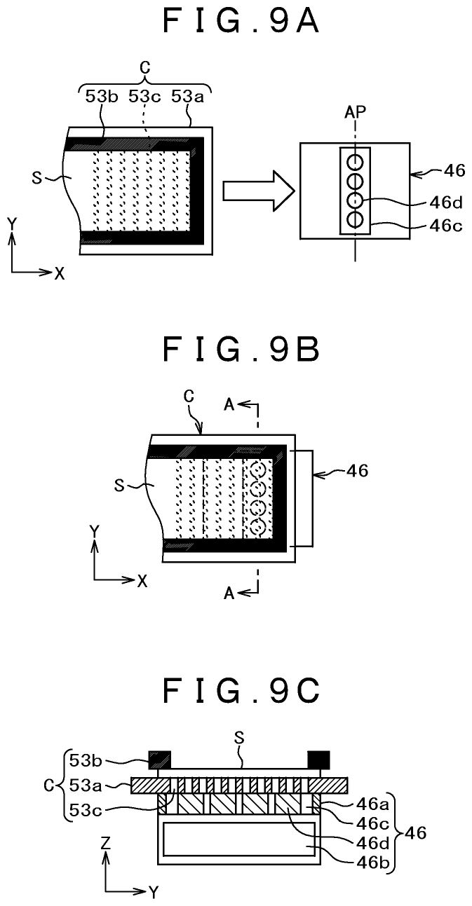

A third modification example will be explained with reference to FIG. 9A, FIG. 9B, and FIG. 9C.

The configuration of a carrier jig C of the third modification example is the same as that of the carrier jig C of the embodiment. In the third modification example, columnar supports 46d are provided only at locations where dies D are positioned (bonded) in the suction port 46c of the mounting section 46a in the bond stage 46 of the embodiment. With this, deformations of a carrier jig C and a substrate S can be reduced when high load bonding is performed. Here, FIG. 9A shows a case where there are four supports 46d, that is, a case where there are four package areas P in one column of the substrate S, but actually, the number of supports 46d to be provided is equal to the number of package areas P existing in one column of the substrate.

### Fourth Modification Example

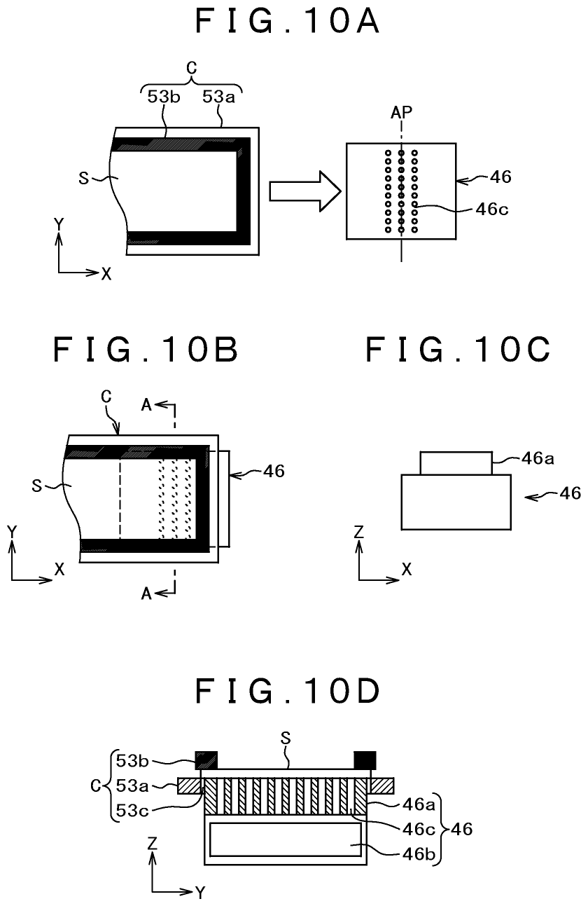

A fourth modification example will be explained with reference to FIG. 10A, FIG. 10B, FIG. 10C, and FIG. 10D.

The configuration of a bond stage 46 of the fourth modification example is the same as that of the bond stage 46 of the first comparative example. In the fourth modification example, one adsorption hole 53c is provided to a carrier jig C of the fourth modification example as an opening larger than the mounting section 46a of the bond stage 46 in the carrier jig C of the first comparative example. With this, since the mounting section 46a directly contacts a substrate S, the bond stage 46 can heat the substrate S directly. In addition, since the suction port 46c of the mounting section 46a of the bond stage 46 is smaller than that of the embodiment, the deformation of the substrate S can be reduced when high load bonding is performed.

As described above, the disclosure made by the present disclosing persons has been specifically described on the basis of the embodiments and modifications, but it goes without saying that the present disclosure is not limited to the above embodiments and modifications, and can be modified in various ways.

For example, although an example in which one large suction port 46c is provided is explained in the embodiment, the suction port 46c can be divided into two or more suction ports in the column direction (Y-axis direction). In this case, a plurality of adsorption holes 53c are positioned within the divided suction ports 46c.

Furthermore, although an example in which one large suction port 46c is provided is explained in the embodiment, it is also conceivable that, by making the width (length in the X-axis direction) of the suction portion 46c smaller and by providing a plurality of grooves that communicate with the suction port 46c, the adsorption holes 53c are made to communicate with the suction port 46c via the grooves.

Although, in the embodiment, an example in which the mounting section 46a of the bond stage 46 is provided with the suction port 46c has been described, the mounting section 46a may be formed of a porous material having a large number of air holes. In this case, it becomes unnecessary to adjust the size of the suction port 46c of the mounting section 46a of the bond stage 46.

In addition, although a DAF is attached to the rear surface of a wafer in the embodiment, a film to be attached to the rear surface may not necessarily be a DAF.

Furthermore, the embodiment is provided with one pickup head and one bond head, but it is conceivable that the embodiment is provide with one or more pickup heads and one or more bond heads. In addition, the embodiment is provided with the intermediate stage, but the intermediate stage is not indispensable. In this case, one head may be shared as a pickup head and a bond head.

What is claimed is:

1. A semiconductor manufacturing apparatus comprising:
a carrier jig including a mounting section having an adsorption hole for adsorbing a substrate to be mounted and a frame section for holding a peripheral edge of the substrate; and
a stage including a mounting section having a suction port communicating with the adsorption hole of the carrier jig to adsorb the substrate and a heating device for heating the substrate.

2. The semiconductor manufacturing apparatus according to claim 1,
wherein the carrier jig includes a plurality of adsorption holes instead of the adsorption hole, and
the suction port of the stage has a size large enough to accommodate the plurality of adsorption holes.

3. The semiconductor manufacturing apparatus according to claim 2,
wherein the adsorption holes of the carrier jig are disposed in the shape of a grid, and
at least one column of the adsorption holes of the carrier jig is positioned within the suction port of the stage.

4. The semiconductor manufacturing apparatus according to claim 3, wherein the stage further includes a support section for supporting a portion where a die is positioned within the suction port.

5. The semiconductor manufacturing apparatus according to claim 3, wherein the stage further includes packing around the periphery of the suction port.

6. The semiconductor manufacturing apparatus according to claim 1, wherein the mounting section of the stage is comprised of a porous material having air holes, and has the air holes of the porous material as a plurality of suction ports instead of the suction port.

7. The semiconductor manufacturing apparatus according to claim 1,
wherein the carrier jig has a plurality of adsorption holes instead of the adsorption hole, and
the mounting section of the stage has a plurality of suction ports instead of the suction port.

8. The semiconductor manufacturing apparatus according to claim 1,
wherein the adsorption hole of the carrier jig has a size large enough for the mounting section of the stage to be inserted thereinto, and
the mounting section of the stage has a plurality of suction ports instead of the suction port.

9. A carrier jig used together with a stage including a mounting section having a suction port for adsorbing a substrate and a heating device for heating the substrate, the carrier jig comprising:
a mounting section having an adsorption hole for adsorbing a substrate to be mounted; and
a frame section for holding a peripheral edge of the substrate to be mounted,
wherein the substrate to be mounted is adsorbed by communication work performed between the adsorption hole and the suction port.

10. A manufacturing method of a semiconductor device comprising the steps of:
conveying a carrier jig on which a substrate is mounted to a bond stage;
mounting the carrier jig on the bond stage; and
adsorbing and heating the substrate mounted on the carrier jig,
wherein the carrier jig includes a mounting section having an adsorption hole for adsorbing the mounted substrate and a frame section for holding a peripheral edge of the mounted substrate, and
the bond stage includes a mounting section having a suction port for adsorbing the mounted substrate via the absorption hole of the carrier jig and a heating device for heating the adsorbed substrate.
